(19) United States
(12) Patent Application Publication
(10) Pub. No.: US 2008/0187823 A1
(43) Pub. Date: Aug. 7, 2008

(54) Protection circuit assembly and battery pack having the same

(76) Inventors: Jeong-Deok Byun, Suwon-si (KR); Kyung-Won Seo, Suwon-si (KR)

Correspondence Address: ROBERT E. BUSHNELL, 1522 K STREET NW, SUITE 300, WASHINGTON, DC, 20005-1202, US

(21) Appl. No.: 11/979,268

(22) Filed: Oct. 31, 2007

(30) Foreign Application Priority Data
Feb. 7, 2007 (KR) 10-2007-0012774

(51) Int. Cl. H01M 10/36; H05K 1/00

(52) U.S. Cl. 429/122; 174/250

(57) ABSTRACT

A protection circuit assembly and a battery pack having the same are capable of preventing a terminal part of a protection circuit board connected to an external terminal from being pushed when the external terminal is electrically connected to the protection circuit assembly. As a result, the external terminal is electrically connected to the protection circuit assembly in a reliable manner. The protection circuit assembly includes: a protection circuit board having at least one projection at its side surface; and an upper case having at least one hole corresponding to the projection. In addition, the battery pack includes: a bare cell; a protection circuit board electrically connected to the bare cell, and having at least one projection at its side surface; and an upper case having at least one hole corresponding to the projection.

### CLAIM OF PRIORITY

This application makes reference to, incorporates the same herein, and claims all benefits accruing under 35 U.S.C. §119 from an application for PROTECTION CIRCUIT ASSEMBLY AND BATTERY PACK HAVING THE SAME earlier filed in the Korean Intellectual Property Office on the 7 Feb. 2007 and there duly assigned Serial No. 2007-0012774.

### BACKGROUND OF THE INVENTION

1. Technical Field

The present invention relates to a protection circuit assembly and a battery pack having the same and, more particularly, to a protection circuit assembly and a battery pack having the same capability of preventing a terminal part of a protection circuit board connected to an external terminal from being pushed when the external terminal is electrically connected to the protection circuit assembly, so that the external terminal is electrically connected to the protection circuit assembly in a reliable manner.

2. Related Art

In recent years, compact and light-weight mobile electronic/electric appliances, such as cellular phones, laptop computers, camcorders and so on, have been actively developed and produced. In order to operate the portable electronic/electric appliances without an external power supply, a battery pack is disposed therein. The battery pack may generally use a Ni—Cd battery, a Ni-MH battery, or a Li battery, which is a secondary battery, i.e., a rechargeable battery, in consideration of economical concerns.

Among them, the Li rechargeable battery has an operating voltage three times larger than that of the Ni—Cd battery or the Ni-MH battery, and an energy density per unit weight larger than that of the Ni—Cd battery or the Ni-MH battery. Therefore, the Li rechargeable battery is widely used for portable electronic/electric appliances. The Li rechargeable battery may be classified into a Li ion battery using a liquid electrolyte and a Li polymer battery using a polymer electrolyte, depending on the kind of electrolyte. The Li rechargeable battery may be classified into a cylindrical type battery, a polygonal type battery, and a pouch type battery depending on its shape.

Generally, the battery pack using the Li rechargeable battery includes a bare cell and a protection circuit assembly. The bare cell includes an electrode assembly, a can, and a cap assembly. The electrode assembly includes: a positive electrode plate having a positive electrode tap connected to a positive electrode collector to which a positive electrode active material is applied; a negative electrode plate having a negative electrode tap connected to a negative electrode collector to which a negative electrode active material is applied; and a separator interposed between the positive electrode plate and the negative electrode plate. The electrode assembly is accommodated in the can, which has an upper opening. The upper opening of the can is sealed by the cap assembly. The protection circuit assembly is electrically connected to the bare cell to prevent the bare cell from being overcharged. The protection circuit assembly includes a protection circuit board for controlling voltage or current when the bare cell is charged or discharged, a lower case disposed between the protection circuit board and the bare cell and providing a space in which the protection circuit board is mounted, and an upper case coupled to the lower case to protect the protection circuit board from external impact.

In general, the lower case of the protection circuit assembly of the battery pack is fabricated by a molding process. However, during the molding process, a molding material such as resin or hot melt is permeated into the terminal part of the protection circuit board so as to cut the electrical connection between the terminal part and the external terminal. In addition, poor fluidity of the molding material may cause cracks or pinholes. In order to solve these problems, a structure in which the protection circuit board is covered with a cover-type upper case has been proposed.

As a result, it is possible to skip the molding process using a structure in which the protection circuit board is covered with a cover-type upper case. However, since coupling between the protection circuit board and the upper case is not strong, when the external terminal is in contact with the terminal part of the protection circuit board so as to electrically connect the protection circuit assembly to the external terminal, the protection circuit may be pushed toward the bare cell so that the external terminal is imperfectly connected to the protection circuit assembly.

### SUMMARY OF THE INVENTION

The present invention provides a protection circuit assembly and a battery pack having the same capability of securely coupling a protection circuit board of a protection circuit assembly to an upper case so as to prevent the protection circuit board from being pushed, thereby electrically connecting the protection circuit assembly to an external terminal in a reliable manner.

According to an aspect of the present invention, a protection circuit assembly includes: a protection circuit board having at least one projection at its side surface; and an upper case having at least one hole corresponding to the projection.

According to another aspect of the present invention, a battery pack includes: a bare cell; a protection circuit board electrically connected to the bare cell and having at least one projection at its side surface; and an upper case having at least one hole corresponding to the projection.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is an exploded perspective view of a bare cell in accordance with a first exemplary embodiment of the present invention;

FIG. 2 is an exploded perspective view of a battery pack in accordance with a first exemplary embodiment of the present invention;

FIG. 3A is an exploded perspective view of a battery pack in accordance with a second exemplary embodiment of the present invention;

FIG. 3B is an exploded perspective view of a battery pack in accordance with a third exemplary embodiment of the present invention;

FIG. 3C is an exploded perspective view of a battery pack in accordance with a fourth exemplary embodiment of the present invention; and

FIG. 3D is an exploded perspective view of a battery pack in accordance with a fifth exemplary embodiment of the present invention.

### DETAILED DESCRIPTION OF THE INVENTION

The present invention will now be described more fully hereinafter with reference to the accompanying drawings, in which exemplary embodiments of the invention are shown. This invention may, however, be embodied in different forms and should not be construed as limited to the embodiments set forth herein. In the drawings, the thickness of layers and regions are exaggerated for clarity. Like numbers refer to like elements throughout the specification.

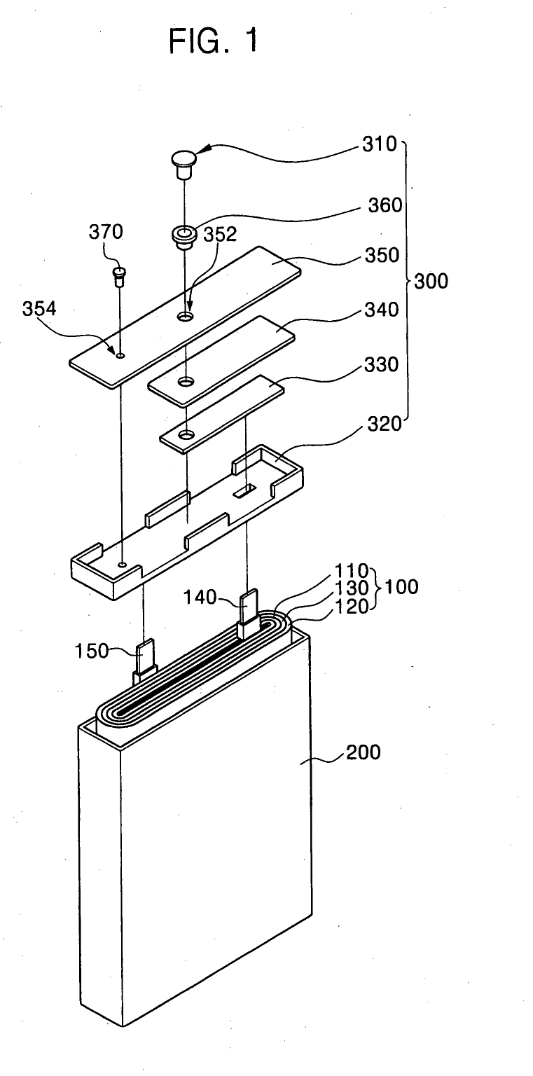

FIG. 1 is an exploded perspective view of a bare cell in accordance with a first exemplary embodiment of the present invention.

Referring to FIG. 1, the bare cell in accordance with the first exemplary embodiment of the present invention includes an electrode assembly 100, a can 200 having an opened upper end and accommodating an electrolyte (not shown) so that a Li ion can move between the electrode assembly 100 and the can 200, and a cap assembly 300 sealing the can 200 and having an electrode terminal 310 electrically connected to the electrode assembly 100. In this process, the electrode assembly 100 includes a positive electrode plate 120 having a positive electrode tap 150 which is connected to a positive electrode collector (not shown) coated with a positive electrode active material (not shown), a negative electrode plate 110 having a negative electrode tap 140 which is connected to a negative electrode collector (not shown) coated with a negative electrode active material (not shown), and a separator 130 disposed between the positive electrode plate 120 and the negative electrode plate 110. In FIG. 1, the negative electrode tap 140 is shown as being disposed at an inner center of the electrode assembly 100, the positive electrode tap 150 is shown as being disposed at an edge of the electrode assembly 100, and the negative electrode tap 140 is shown as being electrically connected to the electrode terminal 310. However, positions of the positive electrode tap 150 and the negative electrode tap 140 may be changed. Alternatively, either one of the positive electrode tap 150 and the negative electrode tap 140 may project toward a lower part of the can 200 so as to be electrically connected to the can 200.

The positive electrode active material may include Li-containing transition metal oxides or Li chalcogenide compounds, for example, typical metal oxides such as LiCoO₂, LiNiO₂, LiMnO₂, LiMn₂O₄, or LiNi_{1-x-y}CoₓM_{y}O₂(wherein 0≦x≦1, 0≦y≦1, 0≦x+y≦1, and M is a metal such a metal such as Al, Sr, Mg, La, and so on). The negative electrode active material may include carbon materials such as crystalline carbon, amorphous carbon, a carbon complex, carbon fiber, and so on, a lithium metal, or a lithium alloy.

The positive electrode collector or the negative electrode collector may be formed of stainless steel, nickel, copper, aluminum, or an alloy thereof. Preferably, the positive electrode collector may be formed of aluminum or an aluminum alloy, and the negative electrode collector may be formed of copper or a copper alloy, thereby maximizing efficiency.

The separator 130 is disposed between the positive electrode plate 120 and the negative electrode plate 110 so as to prevent electrical short circuits and to enable movement of a Li ion. The separator 130 may be formed of a polyolefin-based polymer layer such as polyethylene (PE) or polypropylene (PP), or a multi-layer thereof.

As shown in FIG. 1, the can 200 may be formed of a polygonal metal material, or a cylindrical or pouch metal material, having an upper opening. The metal material may include a light-weight and flexible material such as aluminum, an aluminum alloy, stainless steel, or the like, which allows the can 200 to function as a terminal.

The cap assembly 300 coupled to the upper opening of the can 200 includes a cap plate 350, an insulating plate 340, a terminal plate 330, an insulating case 320, and an electrode terminal 310. The cap plate 350 is a metal plate having a size and shape corresponding to the upper opening of the can 200, and includes a predetermined size of terminal hole 352, an electrolyte injection hole 354, and a safety vent (not shown). The safety vent may be formed at any region where it does not interfere with the terminal hole 352 and the electrolyte injection hole 354, and may be formed at one side surface of the can 200.

The electrolyte injection hole 354 facilitates injection of an electrolyte into the can, in which the electrode assembly 100 is accommodated, so as to smoothly move a Li ion. After sealing the can 200 using the cap assembly 300, the electrolyte is injected through the electrolyte injection hole 354, and the electrolyte injection hole 354 is sealed with an electrolyte injection hole stopper 370 so as to seal the can 200.

The terminal hole 352 facilitates insertion of the electrode terminal 310, and the electrode terminal 310 is electrically connected to the terminal plate 330 disposed under the cap plate 350 through the terminal hole 352. In order to insulate the electrode terminal 310 from the cap plate 350, a gasket 360 formed of an insulating rubber or a non-conductive material is disposed outside the electrode terminal 310.

The insulating plate 340 and the terminal plate 330 are sequentially disposed under the cap plate 350. The terminal plate 330 is electrically connected to the negative electrode tap 140 of the electrode assembly 100 so as to electrically connect the electrode terminal 310 to the negative electrode tap 140. The insulating plate 340 electrically insulates the terminal plate 330 from the cap plate 350 so as to prevent short circuits between the cap plate 350 and the terminal plate 330, even when the cap plate 350 is electrically connected to the positive electrode tap 150 of the electrode assembly 100.

The insulating case 320 is disposed on the upper opening of the can 200 so as to fix the positive electrode tap 150 and the negative electrode tap 140 of the electrode assembly 100. The insulating case 320 may be formed of an insulating polymer resin such as polypropylene (PP), polyphenylene sulphite (PPS), polyethersulfone (PES), metamorphous polyphenylene oxide (PPO), or the like. In order to provide a space for mounting the terminal plate 330 and the insulating plate 340, a support frame may be formed at a periphery of the insulating case 320.

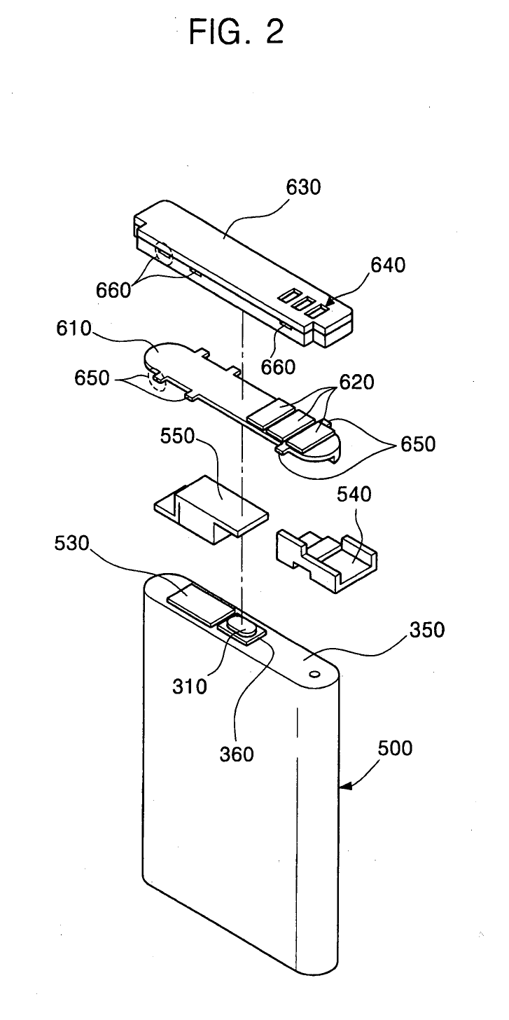

FIG. 2 is an exploded perspective view of a battery pack in accordance with a first exemplary embodiment of the present invention.

Referring to FIG. 2, the battery pack in accordance with a first exemplary embodiment of the present invention includes a bare cell 500 having the electrode terminal 310 shown in FIG. 1, and a protection circuit assembly electrically connected to the bare cell 500 and having a protection circuit board 610 and an upper case 630. The protection circuit board 610 is electrically connected to the electrode terminal 310 and a cap plate 350 through a first lead plate 540 and a second lead plate 550. An insulating member 530 is disposed between the first lead plate 540, electrically connected to the electrode terminal 310, and the cap plate 350.

In this process, while not shown, a board holder (not shown) may be disposed between the protection circuit board 610 and the bare cell 500 to provide secure support between the protection circuit board 610 and the bare cell 500. The board holder may be formed of an insulating material to prevent short circuits between the bare cell 500 and the protection circuit board 610. In addition, the bare cell 500 may be surrounded by an exterior material such as a label, etc. On the other hand, in order to protect the bare cell 500 from external impact, the bare cell 500 may be surrounded by an outer case formed of a steel use stainless (SUS) material.

The protection circuit board 610 includes a terminal part 620 electrically connected to the bare cell 500, and at least one projection 650 formed at both side surfaces thereof. The upper case 630 includes an opening 640 exposing the terminal part 620, and at least one hole 660 corresponding to the projection 650.

In order to check coupling between the protection circuit board 610 and the upper case 630, the projection 650 of the protection circuit board 610 may project by a distance corresponding to the thickness of the upper case 630. In order to readily check the coupling, the projection 650 may have a semi-circular or polygonal shape, or the hole 660 of the upper case 630 may have a rectangular shape.

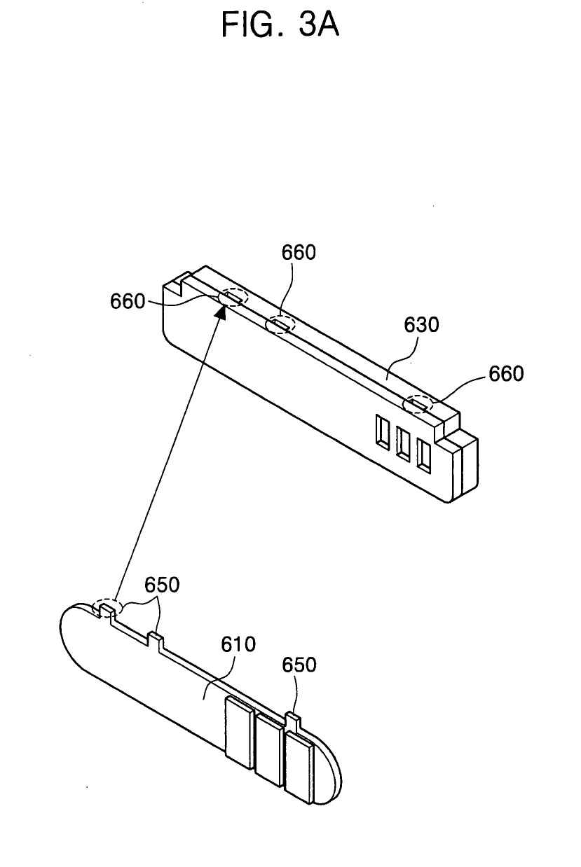

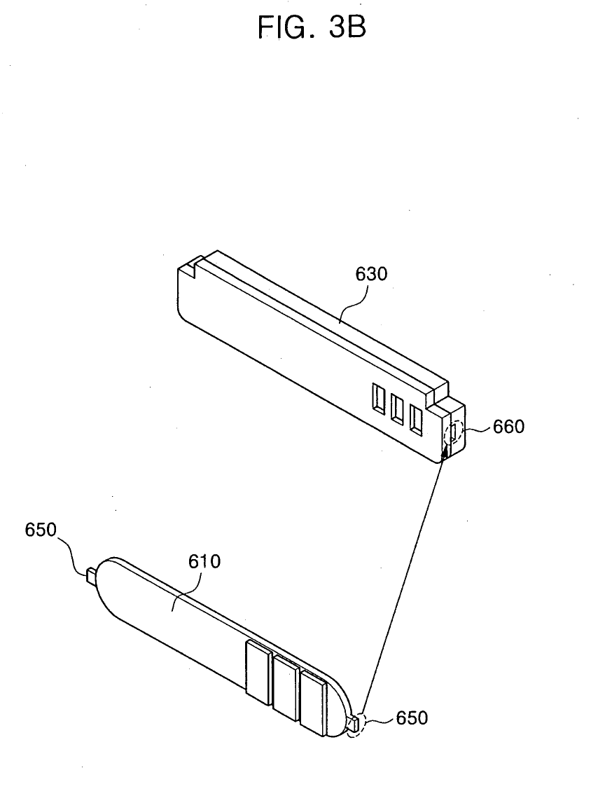

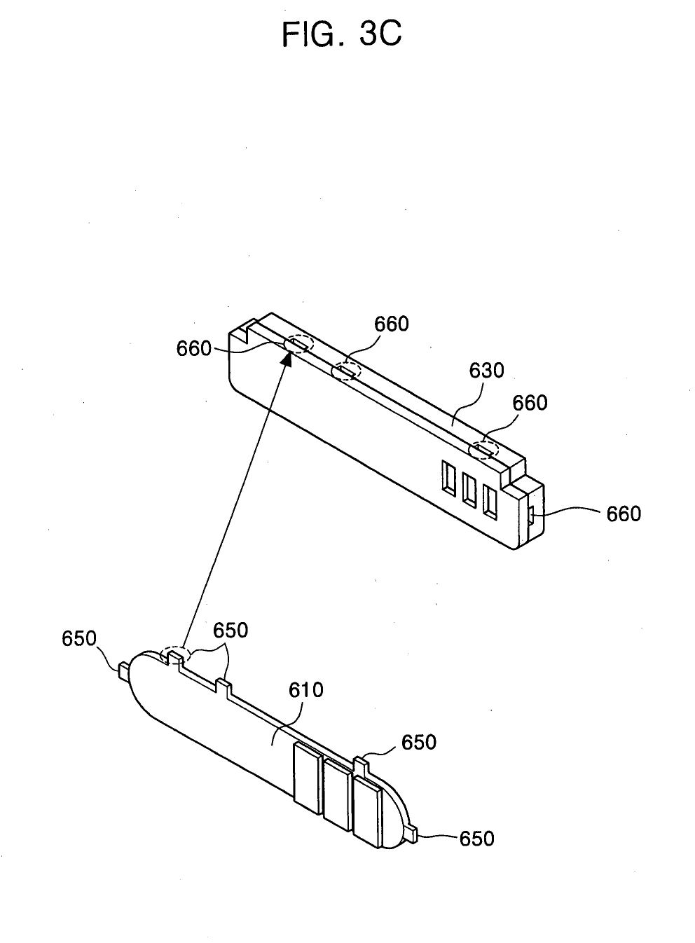

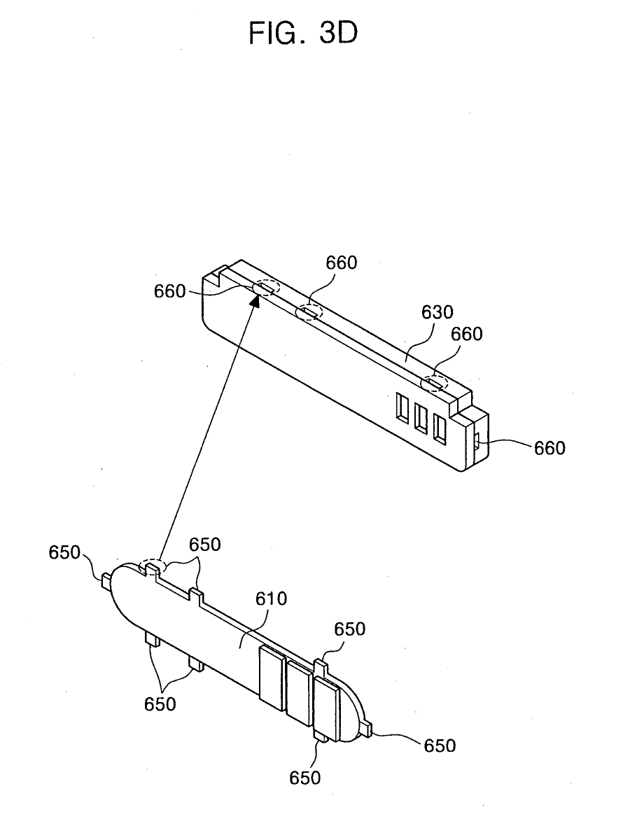

FIG. 3A is an exploded perspective view of a battery pack in accordance with a second exemplary embodiment of the present invention, and FIG. 3B is an exploded perspective view of a battery pack in accordance with a third exemplary embodiment of the present invention.

Referring to FIGS. 3A and 3B, at least one projection 650 and at least one hole 660 are formed in the protection circuit board 610 and the upper case 630, respectively, included in the protection circuit assembly electrically connected to the bare cell 500 in accordance with the first exemplary embodiment of the present invention. The projection 650 and the hole 660 may be formed at one long side surface (FIG. 3A) or both short side surfaces (FIG. 3B) of the protection circuit board 610 and the upper case 630 so that the protection circuit board 610 can be readily coupled to the upper case 630. In addition, the projection 650 and the hole 660 may be formed at one short side surface or both long side surfaces of the protection circuit board 610 and the upper case 630. When the projection 650 and the hole 650 are formed at one side surface of the short side surfaces or the long side surfaces of the protection circuit board 610 and the upper case 630, the other side surface of the upper case 630 may be partially recessed so that the protection circuit board 610 can be readily mounted.

FIG. 3C is an exploded perspective view of a battery pack in accordance with a fourth exemplary embodiment of the present invention, and FIG. 3D is an exploded perspective view of a battery pack in accordance with a fifth exemplary embodiment of the present invention.

Referring to FIGS. 3C and 3D, at least one projection 650 and at least one hole 660 are formed in the protection circuit board 610 and the upper case 630, respectively, included in the protection circuit assembly electrically connected to the bare cell 500 in accordance with the first exemplary embodiment of the present invention. The projection 650 and the hole 660 may be formed at one long side surface and both short side surfaces (FIG. 3C) or both long side surfaces and both short side surfaces (FIG. 3D) of the protection circuit board 610 and the upper case 630. In addition, in contrast to FIGS. 3C and 3D, the projection 650 and the hole 660 may be formed at one short side surface and both long side surfaces of the protection circuit board 610 and the upper case 630. The projection 650 and the hole 660 may be formed at any position of the protection circuit board 610 and the upper case 630, under the condition that the projection 650 and the hole 660 do not weaken coupling between the protection circuit board 610 and the upper case 630.

Eventually, the protection circuit board and the battery pack having the same in accordance with an exemplary embodiment of the present invention includes at least one projection formed at side surfaces of the protection circuit board, and at least one hole corresponding to the projection so that the protection circuit board and the upper case are physically coupled with each other using the projection and the hole, thereby preventing the protection circuit board from being pushed toward the bare cell when the terminal part of the protection circuit board is in contact with the external terminal.

As can be seen from the foregoing, a protection circuit board and a battery pack having the same in accordance with an exemplary embodiment of the present invention include at least one projection formed at side surfaces of a protection circuit board, and at least one hole corresponding to the projection so that the protection circuit board and an upper case are physically coupled with each other using the projection and the hole, thereby preventing the protection circuit board from being pushed toward a bare cell when a terminal part of the protection circuit board is in contact with an external terminal. As a result, it is possible to electrically connect a protection circuit assembly, including the protection circuit board and the upper case, to the external terminal in a reliable manner.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

What is claimed is:

1. A protection circuit assembly, comprising:
a protection circuit board having at least one projection at its side surface; and
an upper case having at least one hole corresponding to the projection.

2. The protection circuit assembly according to claim 1, wherein a number of projections is equal to a number of holes.

3. The protection circuit assembly according to claim 1, wherein said at least one projection has a length equal to a thickness of the upper case.

4. The protection circuit assembly according to claim 1, wherein said at least one projection is formed at one of a short side surface and a long side surface of the protection circuit board.

5. The protection circuit assembly according to claim 4, wherein said at least one projection is formed at both sides of one of a short side surface and a long side surface of the protection circuit board.

6. The protection circuit assembly according to claim 1, wherein said at least one projection is formed at a short side surface and a long side surface of the protection circuit board.

7. The protection circuit assembly according to claim 6, wherein said at least one projection is formed at both short side surfaces and both long side surfaces of the protection circuit board.

8. The protection circuit assembly according to claim 6, wherein said at least one projection is formed at one side of one side surface and both sides of another side surface of a short side surface and a long side surface of the protection circuit board.

9. The protection circuit assembly according to claim 1, wherein said at least one hole has a rectangular shape.

10. The protection circuit assembly according to claim 1, wherein said at least one projection has one of a semi-circular shape and a polygonal shape.

11. A battery pack, comprising:
a bare cell;
a protection circuit board electrically connected to the bare cell and having at least one projection at its side surface; and
an upper case having at least one hole corresponding to the projection.

12. The battery pack according to claim 11, wherein a number of projections is equal to a number of holes.

13. The battery pack according to claim 11, wherein said at least one projection is formed at one of a short side surface and a long side surface of the protection circuit board.

14. The battery pack according to claim 13, wherein said at least one projection is formed at both sides of one side surface of a short side surface and a long side surface of the protection circuit board.

15. The battery pack according to claim 11, wherein said at least one projection is formed at a short side surface and a long side surface of the protection circuit board.

16. The battery pack according to claim 15, wherein said at least one projection is formed at both short side surfaces and both long side surfaces of the protection circuit board.

17. The battery pack according to claim 15, wherein said at least one projection is formed at one side of one side surface and both sides of another side surface of a short side surface and a long side surface of the protection circuit board.

18. The battery pack according to claim 11, wherein said at least one projection has one of a semi-circular shape and a polygonal shape.

19. The battery pack according to claim 11, wherein said at least one hole has a rectangular shape.

20. The battery pack according to claim 11, wherein said at least one projection has a length equal to a thickness of the upper case.

21. The battery pack according to claim 11, further comprising an exterior material surrounding the bare cell.

22. The battery pack according to claim 21, wherein the exterior material comprises a label.

23. The battery pack according to claim 11, further comprising a board holder disposed between the bare cell and the protection circuit board.

24. The battery pack according to claim 23, wherein the board holder is formed of an insulating material.

25. The battery pack according to claim 11, wherein the upper case has an anti-reverse insertion groove formed at one of one short side surface and both short side surfaces thereof.
